(19) United States
(12) Patent Application Publication
(10) Pub. No.: US 2012/0064680 A1
(43) Pub. Date: Mar. 15, 2012

(54) METHODS OF FORMING A CAPACITOR STRUCTURE AND METHODS OF MANUFACTURING SEMICONDUCTOR DEVICES USING THE SAME

(76) Inventors: Jung-Min Oh, Namdong-gu (KR); Bo-Un Yoon, Seoul (KR); Gyu-Wan Choi, Osan-si (KR); Kun-Tack Lee, Suwon-si (KR); Dae-Hyuk Kang, Hwaseong-si (KR); Im-Soo Park, Seongnam-si (KR); Dong-Seok Lee, Hwaseong-si (KR); Young-Hoo Kim, Hwaseong-si (KR)

(21) Appl. No.: 13/228,867

(22) Filed: Sep. 9, 2011

(30) Foreign Application Priority Data
Sep. 15, 2010 (KR) 10-2010-0090390

(51) Int. Cl. H01L 21/336; H01G 13/06

(52) U.S. Cl. 438/239; 216/6; 257/E21.409

(57) ABSTRACT

A method of forming a capacitor structure and manufacturing a semiconductor device, the method of forming a capacitor structure including sequentially forming a first mold layer, a supporting layer, a second mold layer, an anti-bowing layer, and a third mold layer on a substrate having a conductive region thereon; partially removing the third mold layer, the anti-bowing layer, the second mold layer, the supporting layer, and the first mold layer to form a first opening exposing the conductive region; forming a lower electrode on a sidewall and bottom of the first opening, the lower electrode being electrically connected to the conductive region; further removing the third mold layer, the anti-bowing layer, and the second mold layer; partially removing the supporting layer to form a supporting layer pattern; removing the first mold layer; and sequentially forming a dielectric layer and upper electrode on the lower electrode and the supporting layer pattern.

### CROSS-REFERENCE TO RELATED APPLICATION

Korean Patent Application No. 10-2010-0090390, filed on Sep. 15, 2010, in the Korean Intellectual Property Office, and entitled: “Methods of Forming a Capacitor Structure and Methods of Manufacturing Semiconductor Devices Using the Same,” is incorporated by reference herein in its entirety.

### BACKGROUND

1. Field

Embodiments relate to methods of forming a capacitor structure and methods of manufacturing semiconductor devices using the same.

2. Description of the Related Art

As an integration degree of semiconductor devices increases, a capacitor in the semiconductor device may have a high aspect ratio.

### SUMMARY

Embodiments are directed to methods of forming a capacitor structure and methods of manufacturing semiconductor devices using the same.

The embodiments may be realized by providing a method of forming a capacitor structure, the method including sequentially forming a first mold layer, a supporting layer, a second mold layer, an anti-bowing layer, and a third mold layer on a substrate having a conductive region thereon; partially removing the third mold layer, the anti-bowing layer, the second mold layer, the supporting layer, and the first mold layer to form a first opening exposing the conductive region; forming a lower electrode on a sidewall and a bottom of the first opening, the lower electrode being electrically connected to the conductive region; further removing the third mold layer, the anti-bowing layer, and the second mold layer; partially removing the supporting layer to form a supporting layer pattern; removing the first mold layer; and sequentially forming a dielectric layer and an upper electrode on the lower electrode and the supporting layer pattern.

The anti-bowing layer may be formed using silicon oxynitride (SiON) or silicon nitride (SiN).

The supporting layer may be formed using at least one selected from the group of silicon nitride (SiN), silicon carbide (SiC), and silicon carbonitride (SiCN).

The first mold layer may be formed using at least one selected from the group of propylene oxide (POX), boro-phosphor silicate glass (BPSG), and phosphor silicate glass (PSG).

The second and third mold layers may be formed using at least one selected from the group of tetra ethyl ortho silicate (TEOS), plasma enhanced-TEOS (PE-TEOS), and high density plasma-chemical vapor deposition (HDP-CVD) oxide.

Partially removing the third mold layer, the anti-bowing layer, the second mold layer, the supporting layer, and the first mold layer may include performing a dry etching process.

Removing the third mold layer, the anti-bowing layer, and the second mold layer and removing the first mold layer may include performing a wet etching process using fluoric acid (HF) or a buffer oxide etchant (BOE) solution as an etching solution.

The method may further include forming a second opening having a larger width that that of the first opening by performing another partial removal of the third mold layer, the anti-bowing layer, the second mold layer, the supporting layer, and the first mold layer, the other partial removal being performed after forming the first opening.

The second opening may have a substantially vertical sidewall relative to a top surface of the substrate.

Forming the second opening may include performing a wet etching process using fluoric acid or BOE solution as an etching solution.

The method may further include forming an etch stop layer on the substrate prior to forming the first mold layer, wherein forming the first opening includes partially removing the etch stop layer.

The method may further include removing a portion of the etch stop layer exposed by the second opening after forming the second opening.

The substrate may include an impurity region therein, and the conductive region may be a plug electrically connected to the impurity region of the substrate.

Forming the supporting layer pattern may include forming a mask on the supporting layer and the lower electrode; and partially removing the supporting layer using the mask as an etching mask until the first mold layer is exposed.

The embodiments may also be realized by providing a method of manufacturing a semiconductor device, the method including forming a transistor on a substrate such that the transistor including a gate structure and a source/drain region; forming an insulating interlayer covering the transistor and having a plug therethrough such that the plug is electrically connected to the source/drain region; forming a first mold layer, a supporting layer, a second mold layer, an anti-bowing layer, and a third mold layer sequentially on the insulating interlayer and the plug; partially removing the third mold layer, the anti-bowing layer, the second mold layer, the supporting layer, and the first mold layer to form a first opening such that the first opening exposes the plug; forming a lower electrode on a sidewall and a bottom of the first opening such that the lower electrode is electrically connected to the plug; further removing the third mold layer, the anti-bowing layer, and the second mold layer; partially removing the supporting layer to form a supporting layer pattern; removing the first mold layer; and sequentially forming a dielectric layer and an upper electrode on the lower electrode and the supporting layer pattern.

The embodiments may also be realized by providing a method of forming a capacitor structure, the method including providing a substrate; forming an insulating interlayer on the substrate; partially removing portions of the insulating interlayer to form a plurality of plug holes; forming a plurality of plugs in the plug holes; sequentially forming a first mold layer, a supporting layer, a second mold layer, an anti-bowing layer, and a third mold layer on the substrate having the insulating interlayer thereon; partially removing portions of the third mold layer, the anti-bowing layer, the second mold layer, the supporting layer, and the first mold layer to form a plurality of first openings such that the first openings expose the plugs; forming a plurality of lower electrodes on sidewalls and bottoms of the first openings such that the lower electrodes are respectively electrically connected to the plugs; removing remaining portions of the third mold layer, the anti-bowing layer, and the second mold layer; partially removing portions of the supporting layer to form a supporting layer pattern; removing the first mold layer; forming a dielectric layer on the lower electrodes and the supporting layer pattern; forming an upper electrode on the dielectric layer.

Partially removing portions of the supporting layer pattern may include forming openings in the supporting layer such that the openings are between adjacent lower electrodes.

Each of the plurality of first openings may have an inclined sidewall relative to a top surface of the substrate.

Each of the plurality of first openings may have a vertical sidewall relative to a top surface of the substrate.

The vertical sidewall of each of the plurality of first openings may extend vertically from a top surface of the insulating interlayer.

### BRIEF DESCRIPTION OF THE DRAWINGS

The embodiments will become more apparent to those of ordinary skill in the art by describing in detail exemplary embodiments with reference to the attached drawings, in which:

FIGS. 1 to 9 illustrate stages in a method of forming a capacitor structure in accordance with an embodiment;

FIGS. 10 to 12 illustrate cross-sectional views of stages in a method of forming a capacitor structure in accordance with another embodiment;

FIGS. 13 to 15 illustrate cross-sectional views of stages in a method of forming a capacitor structure in accordance with yet another embodiment; and

FIGS. 16 to 18 illustrate cross-sectional views of stages in a method of manufacturing a semiconductor device in accordance with an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” another element or layer, it can be directly connected or coupled to the other element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” other elements or features would then be “upper” elements or features. Thus, the exemplary term “lower” can encompass both an orientation of upper and lower. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

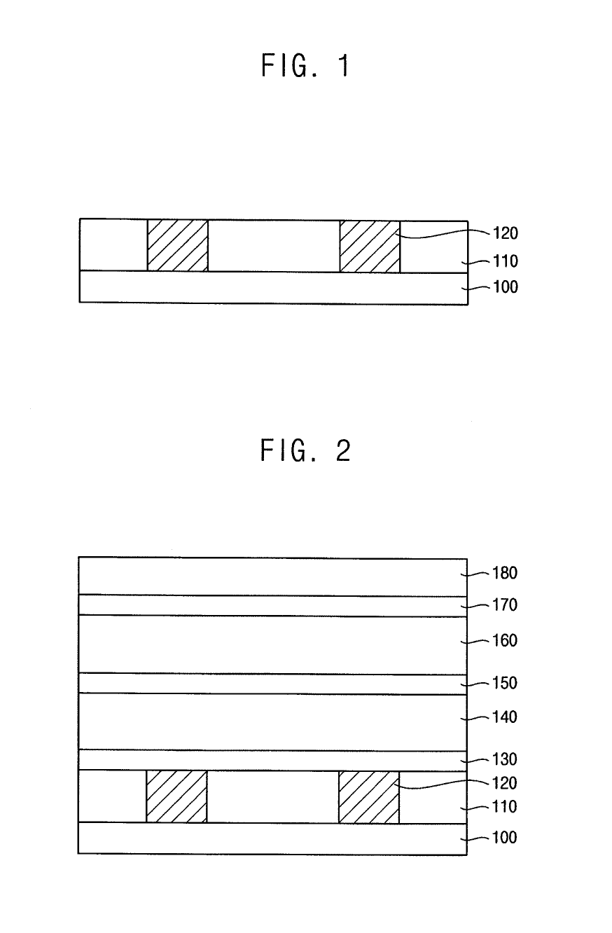

FIGS. 1 to 9 illustrate stages in a method of forming a capacitor structure in accordance with an embodiment.

Referring to FIG. 1, an insulating interlayer 110 may be formed on a substrate 100; and a plug 120 may be formed through the insulating interlayer 110.

The substrate 100 may include a semiconductor substrate, e.g., a silicon (Si) substrate, a germanium (Ge) substrate, a silicon-germanium (Si—Ge) substrate, a silicon-on-insulator (SOI) substrate, a germanium-on-insulator (GOI) substrate, or the like. In an implementation, the substrate 100 may be doped with n-type or p-type impurities.

The insulating interlayer 110 may be formed using an oxide, e.g., silicon oxide. In an implementation, the insulating interlayer 110 may be formed using propylene oxide (POX), undoped silicate glass (USG), spin on glass (SOG), phosphor silicate glass (PSG), boro-phosphor silicate glass (BPSG), flowable oxide (FOX), Tonen Silazane (TOSZ), tetra ethyl ortho silicate (TEOS), plasma enhanced-TEOS (PE-TEOS), high density plasma-chemical vapor deposition (HDP-CVD) oxide, or the like. These may be used alone or in a combination thereof. The insulating interlayer 110 may be formed by a chemical vapor deposition (CVD) process, a plasma-enhanced chemical vapor deposition (PECVD) process, a spin coating process, an HDP-CVD process, or the like.

The insulating interlayer 110 may be partially etched to form a hole (not shown), e.g., a plug hole, exposing a top surface of the substrate 100. A conductive layer (not illustrated) may be formed on the substrate 100 and the insulating interlayer 110 to fill the hole. An upper portion of the conductive layer may be planarized until a top surface of the insulating interlayer 110 is exposed to form the plug 120.

The conductive layer may be formed using doped polysilicon or a metal by a CVD process, a physical vapor deposition (PVD) process, an atomic layer deposition (ALD) process, or the like. The upper portion of the conductive layer may be planarized by a chemical mechanical polishing (CMP) process and/or an etch-back process.

Referring to FIG. 2, an etch stop layer 130, a first mold layer 140, a supporting layer 150, a second mold layer 160, an anti-bowing layer 170, and a third mold layer 180 may be sequentially formed on the insulating interlayer 110 and the plug 120. In an implementation, the second mold layer 160 may not be formed, e.g., the second mold layer 160 may be omitted. Hereinafter, a case in which the second mold layer 160 is formed on the supporting layer 150 will be described.

The etch-stop layer 130 may be formed using silicon nitride by a CVD process, a PECVD process, a low pressure CVD (LPCVD) process, a PVD process, an ALD process, or the like.

The first mold layer 140 may be formed using POX, BPSG, PSG, USG, SOG, FOX, TOSZ, TEOS, PE-TEOS, HDP-CVD oxide, or the like. In an implementation, the first mold layer 140 may be formed using POX, BPSG, or PSG by a CVD process, a PECVD process, a spin coating process, a HDP-CVD process, or a PVD process.

The supporting layer 150 may be formed using silicon nitride (SiN), silicon carbide (SiC), or silicon carbonitride (SiCN) by a CVD process, a PECVD process, a LPCVD process, or the like.

The second mold layer 160 may be formed using TEOS, PE-TEOS, BPSG, PSG, USG, SOG, FOX, TOSZ, HDP-CVD oxide, or the like. In an implementation, the second mold layer 150 may be formed using TEOS, PE-TEOS, or HDP-CVD oxide by a CVD process, a PECVD process, a spin coating process, a HDP-CVD process, or the like.

In an implementation, the second mold layer 160 may be formed using a different material from that of the first mold layer 140. Accordingly, the second mold layer 160 may have a different etching rate from that of the first mold layer 140 with respect to the same etching solution or etching gas.

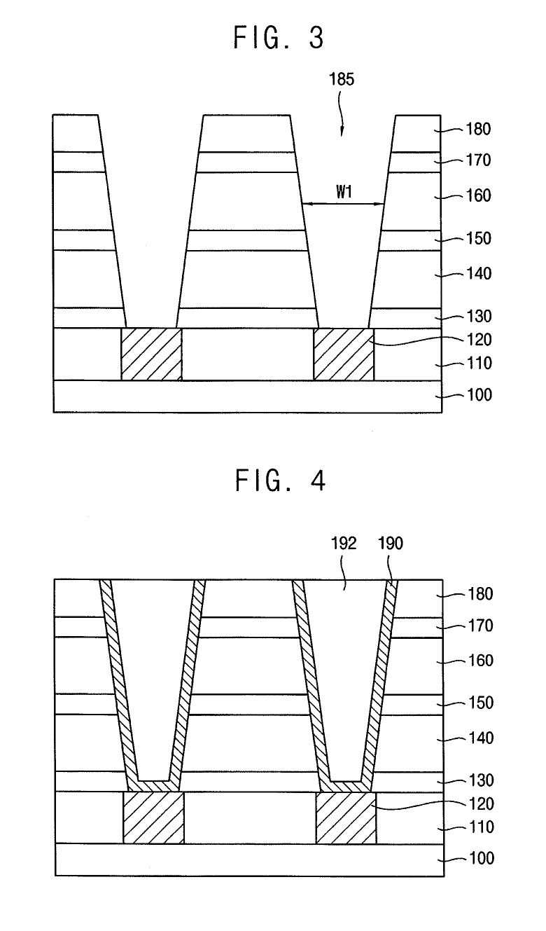

The anti-bowing layer 170 may be formed at a region that corresponds to a region at which a bowing phenomenon may occur by an ion scattering when a first opening 185 (see FIG. 3) is formed. For example, a location or a height of the first mold layer 140, the second mold layer 160, and the anti-bowing layer 170 may be adjusted in order to reduce or prevent the bowing phenomenon. In an implementation, the anti-bowing layer 170 may be formed directly on the supporting layer 150 without forming the second mold layer 160.

The anti-bowing layer 170 may be formed using a material having a lower etching rate than that of the first, second, and third mold layers 140, 160, and 180 with respect to an etching gas for a dry etching process in order to reduce or prevent the bowing phenomenon. In an implementation, the anti-bowing layer 170 may be formed using silicon oxynitride or silicon nitride by a CVD process, a PECVD process, a LPCVD process, an ALD process, or the like.

The third mold layer 180 may be formed using POX, BPSG, PSG, USG, SOG, FOX, TOSZ, TEOS, PE-TEOS, or HDP-CVD oxide by a CVD process, a PECVD process, a spin coating process, a HDP-CVD process, a PVD process, or the like.

In an implementation, the third mold layer 180 may be formed using the same material as that of the second mold layer 160 and a different material from that of the first material 140. Thus, the third mold layer 180 may have a different etching rate from that of the first mold layer 140 with respect to the same etching solution or etching gas (like the second mold layer 160).

Referring to FIG. 3, a photoresist pattern (not shown) may be formed on the third mold layer 180. The third mold layer 180, the anti-bowing layer 170, the second mold layer 160, the supporting layer 150, the first mold layer 140, and the etch stop layer 130 may be sequentially and partially etched using the photoresist pattern as an etching mask to form the first opening 185 exposing the plug 120. In an implementation, the first opening 185 may have a first width (represented by “W1”) that increases along its height. For example, the first opening 185 may become gradually narrower from a top portion to a bottom portion thereof.

The photoresist pattern may be removed by an ashing and/or a stripping process.

In an implementation, the first opening 185 may be formed by a dry etching process in which CH₃F, CHF₃, CF₄, C₂F₆, NF₃, O₂, or Ar may serve as an etching gas. The anti-bowing layer 170 (having a low etching rate with respect to the etching gas) may be formed at a region at which a bowing phenomenon may occur so that the bowing phenomenon may be reduced or prevented during the dry etching process.

Referring to FIG. 4, a lower electrode layer (not illustrated) may be formed on an exposed surface of the plug 120, an inner wall of the first opening 185, and the third mold layer 180. A sacrificial layer (not illustrated) may be formed on the lower electrode layer to sufficiently fill the first opening 185.

The lower electrode layer may be formed using a metal and/or a metal nitride. For example, the lower electrode layer may be formed using titanium, titanium nitride, tantalum, tantalum nitride, aluminum, aluminum nitride, titanium-aluminum nitride, or the like. These may be used alone or in a combination thereof. The lower electrode layer may be formed by a sputtering process, a CVD process, an ALD process, a vacuum deposition process, or the like. The sacrificial layer may be formed using POX, BPSG, PSG, USG, SOG, FOX, TOSZ, TEOS, PE-TEOS, or HDP-CVD oxide.

Upper portions of the sacrificial layer and the lower electrode layer may be planarized until a top surface of the third mold layer 180 is exposed to form a lower electrode 190 (on a sidewall and a bottom of the first opening 185) and a sacrificial layer pattern 192 (filling a remaining portion of the first opening 185).

Referring to FIG. 5, the third mold layer 180, the anti-bowing layer 170, and the second mold layer 160 may be removed. For example, the supporting layer 150 may serve as an etch-stop layer. Thus, the first mold layer 140 and the etch stop layer 130 may not be removed. The sacrificial layer pattern 192 may also be partially or completely removed because the sacrificial layer pattern 192 may not be covered by the supporting layer 150 (acting as an etch-stop layer). In an implementation, an upper portion of the sacrificial layer pattern 192 may be removed (as illustrated in FIG. 5). In an implementation, the third mold layer 180, the anti-bowing layer 170, the second mold layer 160, and the sacrificial layer pattern 192 may be removed by a wet etching process (in which fluoric acid (HF) or a buffer oxide etchant (BOE) solution may serve as an etching solution). The supporting layer 150 may include a material having a very low etching rate with respect to HF or the BOE solution (e.g., silicon nitride, silicon carbide or silicon carbonitride). Therefore, the supporting layer 150 may not be substantially removed during the wet etching process.

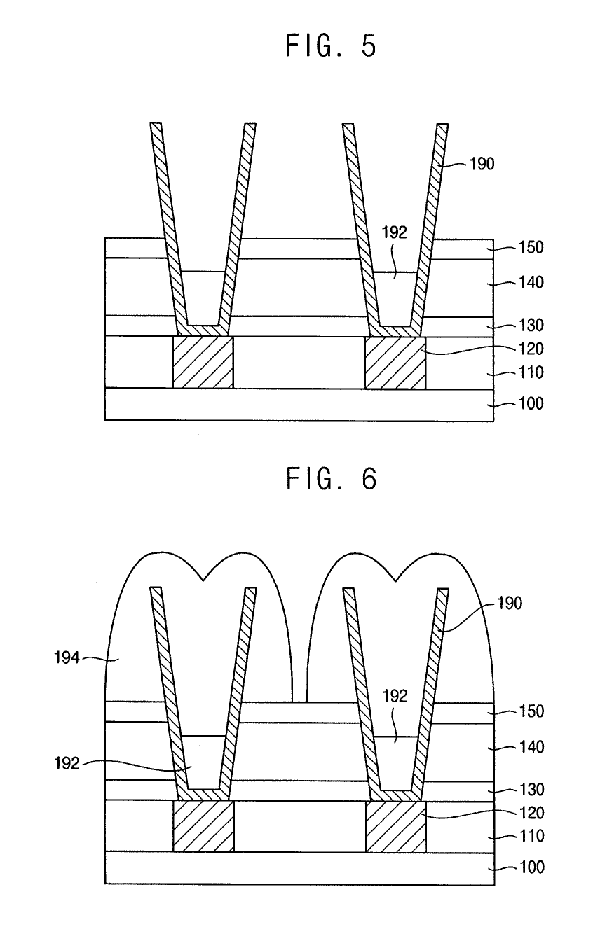

Referring to FIG. 6, a mask 194 may be formed on the supporting layer 150, the lower electrode 190, and the sacrificial layer pattern 192. For example, a mask layer (not illustrated) may be formed on the supporting layer 150, the lower electrode 190, and the sacrificial layer pattern 192. Then, the mask layer may be anisotropically etched to form the mask 194 that partially exposes the supporting layer 150. The mask layer may be formed using POX, BPSG, PSG, USG, SOG, FOX, TOSZ, TEOS, PE-TEOS, HDP-CVD oxide, or the like.

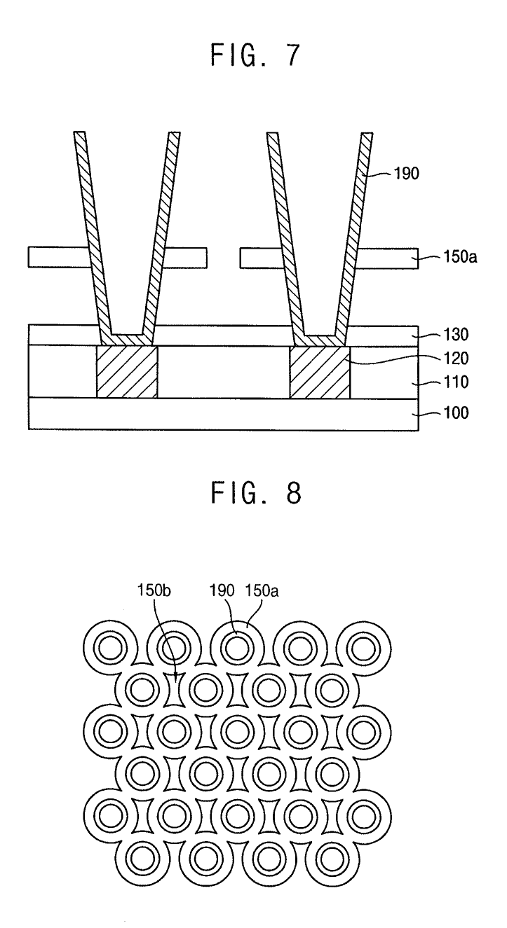

Referring to FIG. 7, the supporting layer 150 may be partially etched using the mask 194 as an etching mask until a top surface of the first mold layer 140 is exposed. Accordingly, a supporting layer pattern 150a partially (exposing the first mold layer 140) may be formed.

The mask 194, the first mold layer 140, and a remaining portion of the sacrificial layer pattern 192 may then be removed. In an implementation, the mask 194, the first mold layer 140, and the sacrificial layer pattern 192 may be removed by a wet etching process in which HF or the BOE may serve as an etching solution. As described above, the supporting layer pattern 150a may include silicon nitride, silicon carbide, or silicon carbonitride. Thus, the supporting layer pattern 150a may not be substantially removed during the wet etching process. The supporting layer pattern 150a may extend along sidewalls of adjacent lower electrodes 190. Therefore, the lower electrode 190 may not lean, bend or collapse, even though the lower electrode 190 may not have a vertical sidewall, e.g., the lower electrode 190 may have an inclined sidewall relative to a top surface of the substrate 100.

Referring to FIG. 8, the supporting layer pattern 150a may have a mesh-type structure. For example, the supporting layer pattern 150a may surround the sidewalls of the lower electrodes 190; and openings 150b may be included between the adjacent lower electrodes 190.

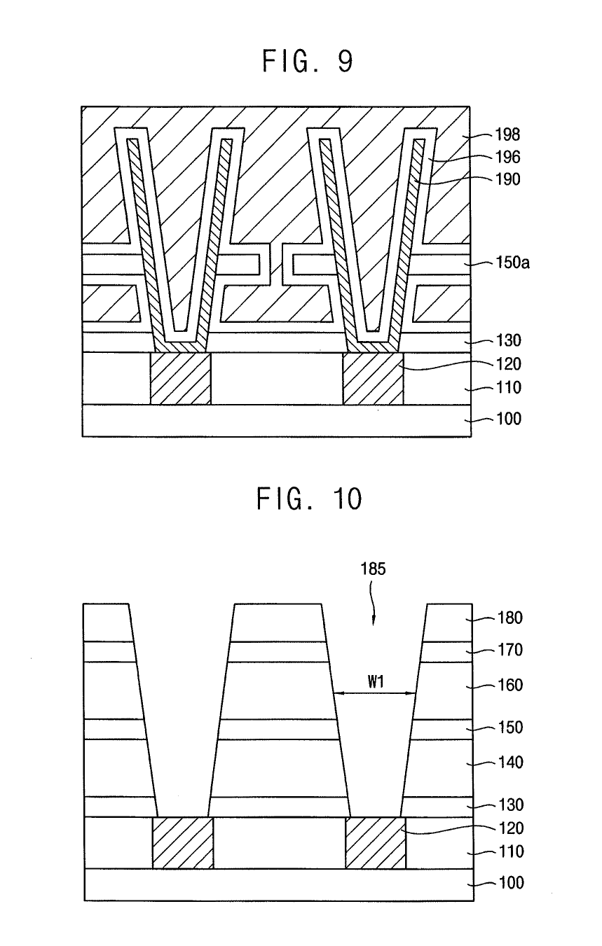

Referring to FIG. 9, a dielectric layer 196 may be formed on the lower electrode 190, the supporting layer pattern 150a, and the etch stop layer 130. An upper electrode 198 may be formed on the dielectric layer 196 to form the capacitor structure.

The dielectric layer 196 may be formed using a material having a higher dielectric constant than that of silicon nitride or silicon oxide. For example, the dielectric layer 196 may be formed using tantalum oxide, hafnium oxide, aluminum oxide, zirconium oxide, or the like. These may be used alone or in a combination thereof. The dielectric layer 196 may be formed by a CVD process, a PVD process, an ALD process, or the like.

The upper electrode 198 may be formed using a metal, a metal nitride, or a doped polysilicon by a CVD process, a PVD process, an ALD process, or the like.

FIGS. 10 to 12 illustrate cross-sectional views of stages in a method of forming a capacitor structure according to another embodiment.

Referring to FIG. 10, processes substantially the same as or similar to those illustrated with reference to FIGS. 1 to 3 may be performed to form the first opening 185.

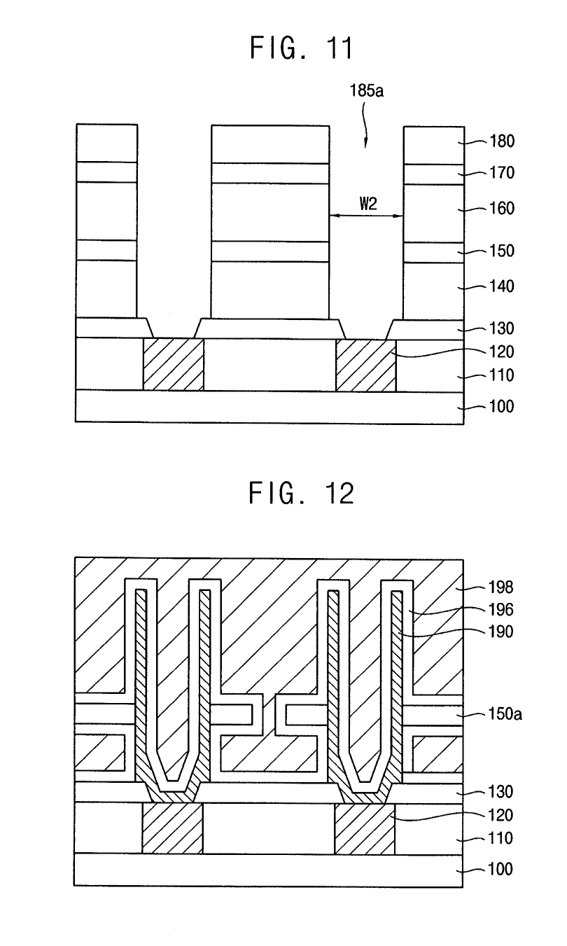

Referring to FIG. 11, a wet etching process may be performed on a sidewall of the first opening 185 to form a second opening 185a (which may have a second width W2 generally larger than the first width W1 of the first opening 185, e.g., W2 may be generally continuous along the second opening 185a).

In an implementation, HF or a BOE solution may be used in the wet etching process. The supporting layer 150, the anti-bowing layer 170, the second mold layer 160, and the third mold layer 180 may have a very low etching rate with respect to the HF or the BOE solution. Accordingly, the first mold layer 140 may be mainly etched during the wet etching process, so that the second opening 185a may have an enlarged lower portion relative to the first opening 185. In an implementation, the second opening 185a may have a substantially vertical sidewall relative to a top surface of the substrate 100. Thus, the lower electrode 190 may have a more stable structure (as seen in FIG. 11).

Referring to FIG. 12, processes substantially the same as or similar to those illustrated with reference to FIGS. 4 to 9 may be performed to form the capacitor structure.

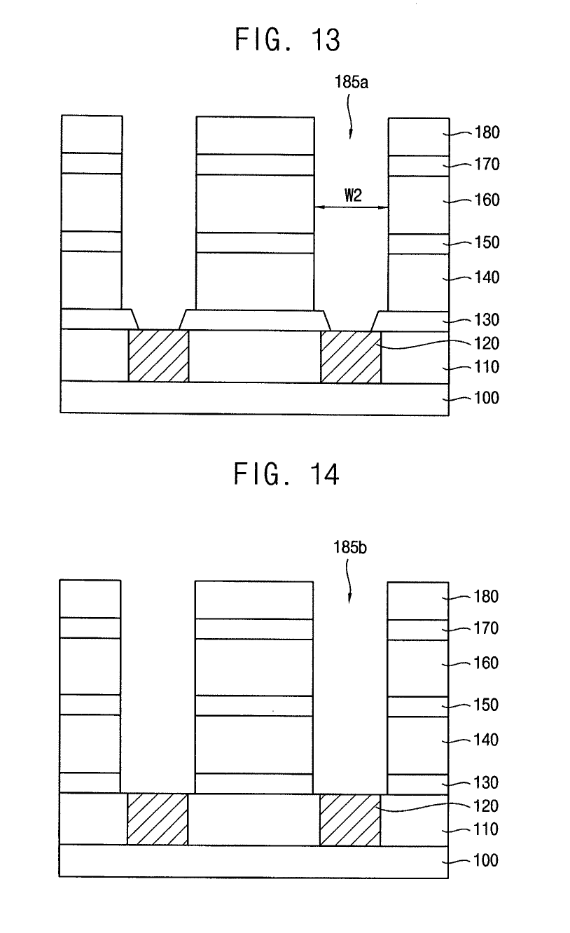

FIGS. 13 to 15 illustrate cross-sectional views of stages in a method of forming a capacitor structure according to yet another embodiment.

Referring to FIG. 13, processes substantially the same as or similar to those illustrated with reference to FIGS. 10 to 11 may be performed to form the second opening 185a.

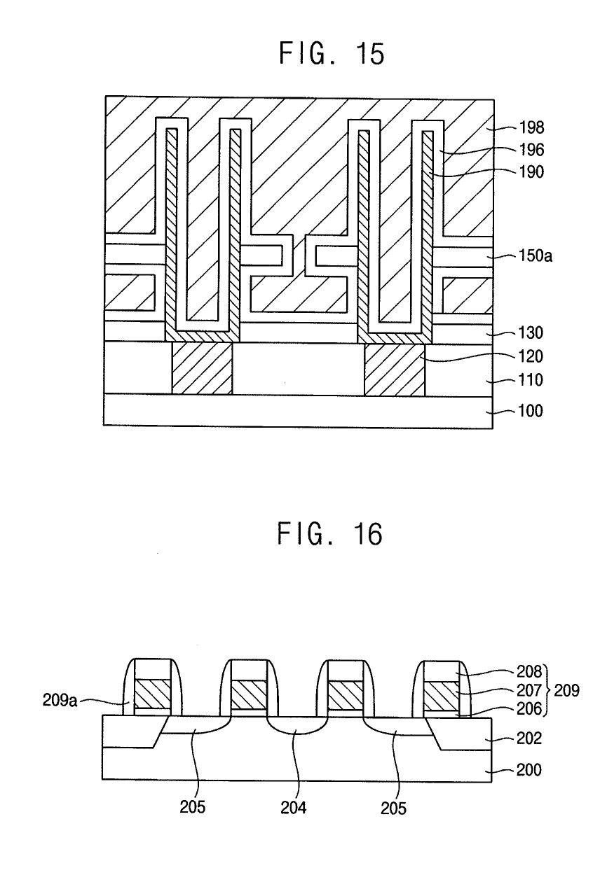

Referring to FIG. 14, a portion of the etch stop layer 130 exposed by the second opening 185a may be removed to form a third opening 185b. Accordingly, a contact area between the lower electrode 190 and the plug 120 may be enlarged to thereby reduce contact resistance (see FIG. 15).

In an implementation, the portion of the etch stop layer 130 may be removed by a wet etching process in which phosphoric acid (H₃PO₄) or sulfuric acid (H₂SO₄) may serve as an etching solution.

Referring to FIG. 15, a process substantially the same as or similar to that illustrated with reference to FIG. 12 may be performed to form the capacitor structure.

FIGS. 16 to 18 illustrate cross-sectional views of stages in a method of manufacturing a semiconductor device in accordance with an embodiment.

Referring to FIG. 16, an isolation layer 202 may be formed on a substrate 200. In an implementation, the isolation layer 202 may be formed by a shallow trench isolation (STI) process.

A gate insulation layer, a gate electrode layer, and a gate mask layer (not illustrated) may be sequentially formed on the substrate 200. The gate mask layer, the gate electrode layer, and the gate insulation layer may be patterned by a photolithography process to form a plurality of gate structures 209 (each including a gate insulation layer pattern 206, a gate electrode 207, and a gate mask 208 sequentially stacked on the substrate 200). The gate insulation layer may be formed using silicon oxide and/or a metal oxide. The gate electrode layer may be formed using a metal or doped polysilicon. The gate mask layer may be formed using silicon nitride.

Impurities may be implanted onto the substrate 200 using the gate structures 209 as an ion-implantation mask to form first and second impurity regions 204 and 205 (at upper portions of the substrate 200 adjacent to the gate structures 209). The first and second impurity regions 204 and 205 may serve as source/drain regions. The gate structure 209 and the impurity regions 204 and 205 may form a transistor. Further, a spacer 209a including silicon nitride may be formed on a sidewall of each gate structure 209.

Referring to FIG. 17, a first insulating interlayer 210 may be formed on the substrate 200 to cover the gate structures 209 and the spacers 209a. The first insulating interlayer 210 may be partially removed to form a first hole (not shown) exposing the impurity regions 204 and 205. In an implementation, the first hole may be self-aligned with the gate structure 209 and the spacer 209a.

A first conductive layer (not illustrated) may be formed on the substrate 200 and the first insulating interlayer 210 to fill the first hole. An upper portion of the first conductive layer may be planarized until a top surface of the first insulating interlayer 210 is exposed to form first and second plugs 217 and 219. The first and second plugs 217 and 219 may be electrically connected to the first and second impurity regions 204 and 205, respectively. The first conductive layer may be found using a metal or doped polysilicon. The first plug 217 may serve as a bit line contact.

A second conductive layer (not shown) may be formed on the first plug 217 and the first insulating interlayer 210 and may then be patterned to form a bit line (not shown). The second conductive layer may be formed using a metal or doped polysilicon.

A second insulating interlayer 215 may be formed on the first insulating interlayer 210 to cover the bit line. The second insulating interlayer 215 may be partially etched to form a second hole (not shown) exposing the second plug 219. A third conductive layer (not illustrated) may be formed on the second plug 219 and the second insulating interlayer 215 to fill the second hole. An upper portion of the third conductive layer may be planarized by a CMP process and/or an etch-back process until a top surface of the second insulating interlayer 215 is exposed to form a third plug 220 filling the second hole. The third conductive layer may be formed using a metal or doped polysilicon. The second and third plugs 219 and 220 may serve as a capacitor contact. Alternatively, the third plug 220 may be formed to make a direct contact with the second impurity region 205 through the first and second insulating interlayers 210 and 215, without forming the second plug 219.

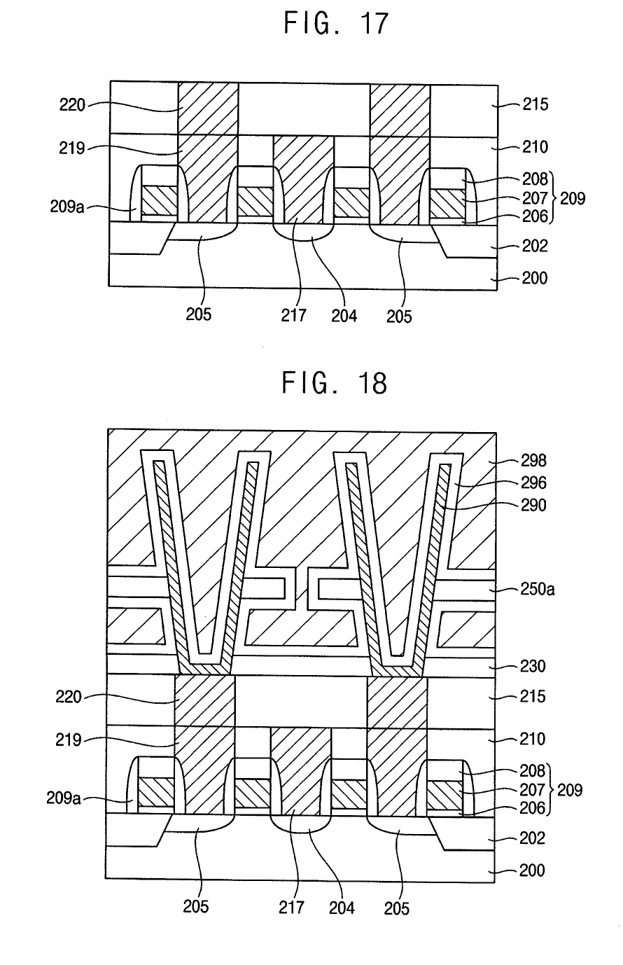

Referring to FIG. 18, processes substantially the same as or similar to those illustrated with reference to FIGS. 1 to 9 may be performed to form a capacitor structure.

For example, an etch-stop layer 230 may be formed on the second insulating interlayer 215 to expose the third plug 220; and a lower electrode 290 contacting the third plug 220 may be formed. A supporting layer pattern 250a (supporting the lower electrode 290) may be formed on sidewalls of the lower electrode 290. A dielectric layer 296 may be formed on the lower electrode 290, the supporting layer pattern 250a, and the etch stop layer 230. An upper electrode 298 may be formed on the dielectric layer 296 to form the capacitor structure.

In another implementation, processes substantially the same as or similar to those illustrated with reference to FIGS. 10 to 15 may be performed to form a lower electrode having a substantially vertical sidewall relative to the substrate 200.

By way of summation and review, without the advance reflected in the embodiments described herein, a lower electrode of a capacitor in a semiconductor device may lean or collapse. Further, when a contact hole for forming the lower electrode is formed by etching a mold layer, an upper portion of the contact hole may be excessively etched to cause a bowing phenomenon so that a width of the upper portion of the contact hole may become larger than that of other portions. Therefore, a distance between adjacent lower electrodes may become smaller so that a short-circuit may occur and the lower electrode may severely lean or collapse.

Accordingly, the embodiments provide a method of forming a capacitor structure having a good structural stability.

According to the embodiments, in the formation of a capacitor structure, an anti-bowing layer having a lower etching rate than that of a mold layer may be formed so that a short-circuit between neighboring lower electrodes may be reduced or prevented. Additionally, a supporting layer that supports the lower electrode may be formed to reduce or prevent the lower electrode (having a high aspect ratio) from leaning or collapsing.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of forming a capacitor structure, the method comprising:
sequentially forming a first mold layer, a supporting layer, a second mold layer, an anti-bowing layer, and a third mold layer on a substrate having a conductive region thereon;
partially removing the third mold layer, the anti-bowing layer, the second mold layer, the supporting layer, and the first mold layer to form a first opening exposing the conductive region;
forming a lower electrode on a sidewall and a bottom of the first opening, the lower electrode being electrically connected to the conductive region;
further removing the third mold layer, the anti-bowing layer, and the second mold layer;
partially removing the supporting layer to form a supporting layer pattern;
removing the first mold layer; and
sequentially forming a dielectric layer and an upper electrode on the lower electrode and the supporting layer pattern.

2. The method as claimed in claim 1, wherein the anti-bowing layer is formed using silicon oxynitride (SiON) or silicon nitride (SiN).

3. The method as claimed in claim 1, wherein the supporting layer is formed using at least one selected from the group of silicon nitride (SiN), silicon carbide (SiC), and silicon carbonitride (SiCN).

4. The method as claimed in claim 1, wherein the first mold layer is formed using at least one selected from the group of propylene oxide (POX), boro-phosphor silicate glass (BPSG), and phosphor silicate glass (PSG).

5. The method as claimed in claim 1, wherein the second and third mold layers are formed using at least one selected from the group of tetra ethyl ortho silicate (TEOS), plasma enhanced-TEOS (PE-TEOS), and high density plasma-chemical vapor deposition (HDP-CVD) oxide.

6. The method as claimed in claim 1, wherein partially removing the third mold layer, the anti-bowing layer, the second mold layer, the supporting layer, and the first mold layer includes performing a dry etching process.

7. The method as claimed in claim 1, wherein removing the third mold layer, the anti-bowing layer, and the second mold layer and removing the first mold layer include performing a wet etching process using fluoric acid (HF) or a buffer oxide etchant (BOE) solution as an etching solution.

8. The method as claimed in claim 1, further comprising forming a second opening having a larger width that that of the first opening by performing another partial removal of the third mold layer, the anti-bowing layer, the second mold layer, the supporting layer, and the first mold layer, the another partial removal being performed after forming the first opening.

9. The method as claimed in claim 8, wherein the second opening has a substantially vertical sidewall relative to a top surface of the substrate.

10. The method as claimed in claim 8, wherein forming the second opening includes performing a wet etching process using fluoric acid or BOE solution as an etching solution.

11. The method as claimed in claim 8, further comprising forming an etch stop layer on the substrate prior to forming the first mold layer,
wherein forming the first opening includes partially removing the etch stop layer.

12. The method as claimed in claim 11, further comprising removing a portion of the etch stop layer exposed by the second opening after forming the second opening.

13. The method as claimed in claim 1, wherein:
the substrate includes an impurity region therein, and
the conductive region is a plug electrically connected to the impurity region of the substrate.

14. The method as claimed in claim 1, wherein forming the supporting layer pattern includes:
forming a mask on the supporting layer and the lower electrode; and
partially removing the supporting layer using the mask as an etching mask until the first mold layer is exposed.

15. A method of manufacturing a semiconductor device, the method comprising:
forming a transistor on a substrate such that the transistor including a gate structure and a source/drain region;
forming an insulating interlayer covering the transistor and having a plug therethrough such that the plug is electrically connected to the source/drain region;
forming a first mold layer, a supporting layer, a second mold layer, an anti-bowing layer, and a third mold layer sequentially on the insulating interlayer and the plug;
partially removing the third mold layer, the anti-bowing layer, the second mold layer, the supporting layer, and the first mold layer to form a first opening such that the first opening exposes the plug;
forming a lower electrode on a sidewall and a bottom of the first opening such that the lower electrode is electrically connected to the plug;
further removing the third mold layer, the anti-bowing layer, and the second mold layer;
partially removing the supporting layer to form a supporting layer pattern;
removing the first mold layer; and
sequentially forming a dielectric layer and an upper electrode on the lower electrode and the supporting layer pattern.

16. A method of forming a capacitor structure, the method comprising:
providing a substrate;
forming an insulating interlayer on the substrate;
partially removing portions of the insulating interlayer to form a plurality of plug holes;
forming a plurality of plugs in the plug holes;
sequentially forming a first mold layer, a supporting layer, a second mold layer, an anti-bowing layer, and a third mold layer on the substrate having the insulating interlayer thereon;
partially removing portions of the third mold layer, the anti-bowing layer, the second mold layer, the supporting layer, and the first mold layer to form a plurality of first openings such that the first openings expose the plugs;
forming a plurality of lower electrodes on sidewalls and bottoms of the first openings such that the lower electrodes are respectively electrically connected to the plugs;
removing remaining portions of the third mold layer, the anti-bowing layer, and the second mold layer;
partially removing portions of the supporting layer to form a supporting layer pattern;
removing the first mold layer;
forming a dielectric layer on the lower electrodes and the supporting layer pattern;
forming an upper electrode on the dielectric layer.

17. The method as claimed in claim 16, wherein partially removing portions of the supporting layer pattern includes forming openings in the supporting layer such that the openings are between adjacent lower electrodes.

18. The method as claimed in claim 16, wherein each of the plurality of first openings has an inclined sidewall relative to a top surface of the substrate.

19. The method as claimed in claim 16, wherein each of the plurality of first openings has a vertical sidewall relative to a top surface of the substrate.

20. The method as claimed in claim 19, wherein the vertical sidewall of each of the plurality of first openings extends vertically from a top surface of the insulating interlayer.
